(19) United States
(12) Patent Application Publication
(10) Pub. No.: US 2025/0393317 A1
(43) Pub. Date: Dec. 25, 2025

(54) LIGHT-RECEIVING ELEMENT, LIGHT-RECEIVING DEVICE, AND METHOD OF MANUFACTURING LIGHT-RECEIVING ELEMENT

(71) Applicant: NICHIA CORPORATION, Anan-shi (JP)

(72) Inventor: Takuya KADOWAKI, Yokohama-shi (JP)

(73) Assignee: NICHIA CORPORATION, Anan-shi (JP)

(21) Appl. No.: 19/246,883

(22) Filed: Jun. 24, 2025

(30) Foreign Application Priority Data
Jun. 25, 2024 (JP) 2024-102141

(51) Int. Cl. H10F 30/223; H10F 71/00; H10F 77/00; H10F 77/14; H10F 77/40; H10F 77/50

(52) U.S. Cl. CPC H10F 30/223; H10F 71/121; H10F 77/147; H10F 77/407; H10F 77/50; H10F 77/933

(57) ABSTRACT

A light-receiving element includes a substrate, a semiconductor layer, and an insulating layer positioned between the substrate and the semiconductor layer in a first direction. The semiconductor layer includes an n-type region, a p-type region, and a mesa portion positioned between the n-type region and the p-type region in a second direction orthogonal to the first direction, the mesa portion having an upper surface, and lateral surface inclined with respect to the upper surface. A length of the mesa portion in the second direction decreases from a side closer to the insulating layer toward the upper surface. The mesa portion includes, in a surface layer region having the upper surface and the lateral surfaces, a light absorption region that can absorb light having a wavelength longer than a wavelength corresponding to a band gap energy of a material constituting the semiconductor layer.

### CROSS-REFERENCE TO RELATED APPLICATION

This application claims priority to Japanese Patent Application No. 2024-102141, filed on Jun. 25, 2024, the disclosure of which is hereby incorporated by reference in its entirety.

### TECHNICAL FIELD

The present disclosure relates to a light-receiving element, a light-receiving device and a method of manufacturing the light-receiving element.

### BACKGROUND

For example, Japanese Patent Publication No. 2010-114183 discloses an infrared detector that utilizes absorption of light in crystal defects in silicon.

### SUMMARY

An object of the present disclosure is to provide a light-receiving element that can improve light-receiving sensitivity, a light-receiving device, and a method of manufacturing the light-receiving element.

According to an aspect of the present disclosure, a light-receiving element includes a substrate, a semiconductor layer, and an insulating layer positioned between the substrate and the semiconductor layer in a first direction, the first direction being a direction from the substrate toward the semiconductor layer, in which the semiconductor layer includes an n-type region, a p-type region, and a mesa portion positioned between the n-type region and the p-type region in a second direction orthogonal to the first direction, the mesa portion having an upper surface and lateral surface inclined with respect to the upper surface, a length of the mesa portion in the second direction decreases from a side closer to the insulating layer toward the upper surface, and the mesa portion includes, in a surface layer region having the upper surface and the lateral surface, a light absorption region that can absorb light having a wavelength longer than a wavelength corresponding to a band gap energy of a material constituting the semiconductor layer.

According to an aspect of the present disclosure, a light-receiving device includes the above light-receiving element, and a lens configured to condense external light toward an end surface of the mesa portion, the end surface facing a third direction orthogonal to the first direction and the second direction.

According to an aspect of the present disclosure, a method of manufacturing a light-receiving element includes providing a structure including a substrate, a semiconductor layer, and an insulating layer positioned between the substrate and the semiconductor layer in a first direction, the first direction being a direction from the substrate toward the semiconductor layer, the semiconductor layer including an n-type region, a p-type region, and a mesa portion positioned between the n-type region and the p-type region in a second direction orthogonal to the first direction, the mesa portion having an upper surface and lateral surfaces inclined with respect to the upper surface, a length of the mesa portion in the second direction decreasing from a side closer to the insulating layer toward the upper surface, and performing ion implantation with a predetermined energy from above the upper surface to a surface layer region having the upper surface and the lateral surfaces of the mesa portion in a state in which the n-type region and the p-type region are covered by a mask.

According to the present disclosure, it is possible to provide a light-receiving element that can improve light-receiving sensitivity, a light-receiving device, and a method of manufacturing the light-receiving element.

### BRIEF DESCRIPTION OF DRAWINGS

FIG. 1 is a schematic plan view illustrating a light-receiving element according to an embodiment.

FIG. 2 is a schematic cross-sectional view taken along the line II-II in FIG. 1.

FIG. 3 is a schematic cross-sectional view of a light-receiving device according to the embodiment.

FIG. 4A is a schematic cross-sectional view for describing a process in a method of manufacturing the light-receiving element according to the embodiment.

FIG. 4B is a schematic cross-sectional view for describing a process in the method of manufacturing the light-receiving element according to the embodiment.

FIG. 4C is a schematic cross-sectional view for describing a process in the method of manufacturing the light-receiving element according to the embodiment.

FIG. 4D is a schematic cross-sectional view for describing a process in the method of manufacturing the light-receiving element according to the embodiment.

FIG. 4E is a schematic cross-sectional view for describing a process in the method of manufacturing the light-receiving element according to the embodiment.

FIG. 4F is a schematic cross-sectional view for describing a process in the method of manufacturing the light-receiving element according to the embodiment.

FIG. 5 is a graph illustrating results of a first experiment.

FIG. 6 is a graph illustrating results of a second experiment.

FIG. 7 is a graph illustrating results of a third experiment.

FIG. 8 is a schematic cross-sectional view of a first sample used in the first experiment.

FIG. 9 is a schematic cross-sectional view of a second sample used in the second experiment.

FIG. 10A is a schematic cross-sectional view of a third-A sample used in the third experiment.

FIG. 10B is a schematic cross-sectional view of a third-B sample used in the third experiment.

FIG. 10C is a schematic cross-sectional view of a third-C sample used in the third experiment.

### DETAILED DESCRIPTIONS

An embodiment is described below with reference to the drawings. Dimensions, materials, shapes, relative arrangements, or the like of constituent members described in the embodiment are not intended to limit the scope of the present disclosure thereto, unless otherwise specified, and are merely exemplary. Note that the sizes, positional relationship, or the like of members illustrated in each of the drawings may be exaggerated for clarity of description. Furthermore, in the following description, members having the same names and reference signs represent the same or similar members, and a repeated detailed description of these members is omitted as appropriate. As a cross-sectional view, an end view illustrating only a cut surface may be illustrated.

In the following description, terms indicating specific directions or positions (for example, “upper,” “lower,” “horizontal,” “vertical,” and other terms related to those terms) may be used. However, these terms are used merely for making it easy to understand relative directions or positions in the referenced drawing. As long as the relative direction or position is the same as that described in the referenced drawing using such terms in drawings other than the drawings of the present disclosure, actual products, and the like, components need not be arranged in the same manner as that in the referenced drawing. For example, on the assumption that there are two members, the positional relationship expressed as “upper,” “on,” “lower,” or “below” in the present specification may include a case in which the two members are in contact with each other and a case in which the two members are not in contact with each other and one of the two members is located above (or below) the other member. Further, in the present specification, a height, a thickness, and a length of a member in a specific direction respectively represent maximum values of the height, the thickness, and the length.

### Light-Receiving Element

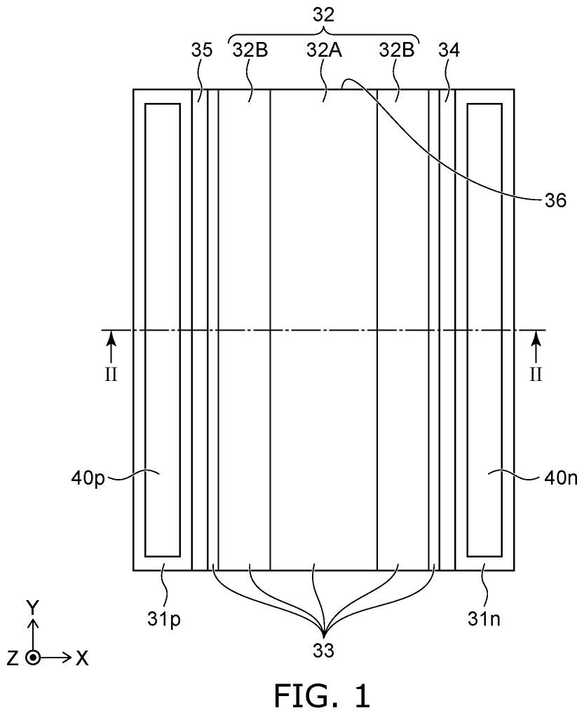

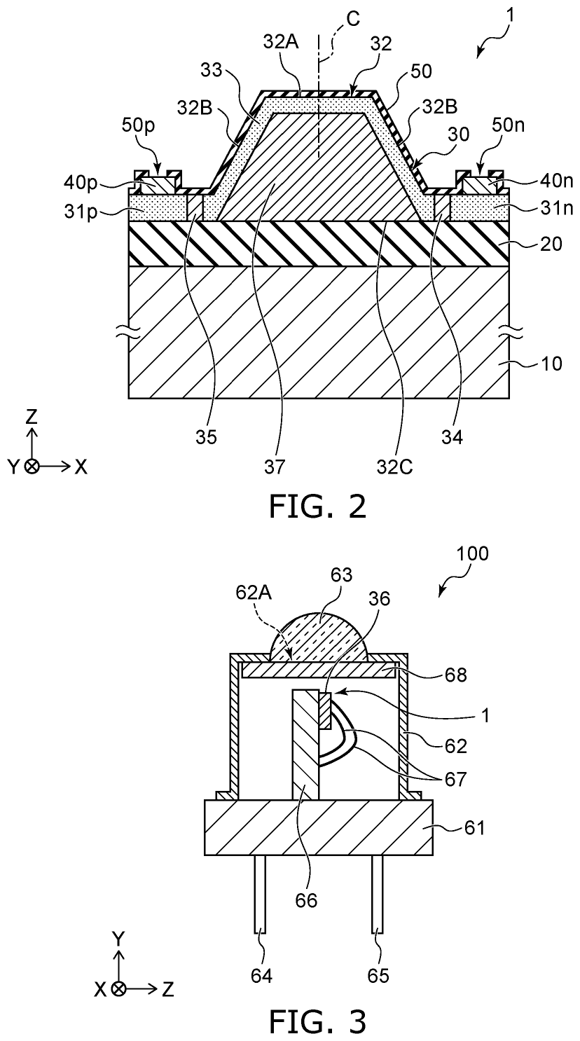

A light-receiving element 1 according to the embodiment will be described with reference to FIGS. 1 and 2. An insulating film 50 is not illustrated in FIG. 1 to make it easy to see a configuration covered with the insulating film 50 in a plan view. In addition, in a cross-sectional view of FIG. 2 and the like, an n-type region 31n, a p-type region 31p, and a light absorption region 33 in a semiconductor layer 30 are represented using dot pattern hatching.

The light-receiving element 1 according to the embodiment includes a substrate 10, the semiconductor layer 30, and an insulating layer 20. A direction from the substrate 10 toward the semiconductor layer 30 is referred to as a first direction Z. Further, two directions orthogonal to the first direction Z are referred to as a second direction X and a third direction Y. The second direction X and the third direction Y are orthogonal to each other.

The substrate 10 is, for example, a silicon substrate. The substrate 10 supports the semiconductor layer 30 with the insulating layer 20 interposed therebetween. The insulating layer 20 is positioned between the substrate 10 and the semiconductor layer 30 in the first direction Z. The insulating layer 20 is, for example, a silicon oxide layer. The semiconductor layer 30 is, for example, a silicon layer. The light-receiving element 1 according to the embodiment has, for example, a silicon on insulator (SOI) structure.

The semiconductor layer 30 includes the n-type region 31n and the p-type region 31p. For example, in the semiconductor layer 30 which is a silicon layer, the n-type region 31n contains phosphorus (P), arsenic (As), antimony (Sb), or bismuth (Bi) as an n-type impurity, and the p-type region 31p contains boron (B), aluminum (Al), gallium (Ga), or indium (In) as a p-type impurity. The n-type region 31n and the p-type region 31p are separated from each other in the second direction X. The n-type region 31n and the p-type region 31p elongated in the third direction Y.

The semiconductor layer 30 further includes a mesa portion 32. The mesa portion 32 is positioned between the n-type region 31n and the p-type region 31p in the second direction X and elongated in the third direction Y. The mesa portion 32 includes an upper surface 32A and lateral surface(s) 32B inclined with respect to the upper surface 32A. The mesa portion 32 includes a lower surface 32C in contact with the insulating layer 20. The upper surface 32A is positioned on a side opposite to the lower surface 32C in the first direction Z. The upper surface 32A and the lower surface 32C are elongated in the third direction Y. Two lateral surfaces 32B are separated from each other in the second direction X. One lateral surface 32B of the two lateral surfaces 32B is positioned beside the n-type region 31n in the second direction X. The other lateral surface 32B is positioned beside the p-type region 31p in the second direction X. The two lateral surfaces 32B extend in the third direction Y. A shape of the mesa portion 32 in a cross section parallel to an XZ plane is trapezoidal. A length of the upper surface 32A in the second direction X is smaller than a length of the lower surface 32C in the second direction X. A length of the mesa portion 32 in the second direction X decreases from the lower surface 32C closer to the insulating layer 20 toward the upper surface 32A.

The mesa portion 32 includes a light absorption region 33 in a surface layer region including the upper surface 32A and the lateral surface(s) 32B. The light absorption region 33 can absorb light having a wavelength longer than the wavelength corresponding to a band gap energy of a material constituting the semiconductor layer 30. In the example of the present embodiment, the light absorption region 33 can absorb infrared light having a wavelength longer than the wavelength corresponding to the band gap energy of silicon constituting the semiconductor layer 30. The light absorption region 33 is a region containing boron, germanium, or magnesium in addition to silicon. It is considered that the light absorption region 33 absorbs light having a wavelength longer than the wavelength corresponding to the band gap energy of silicon by using a defect level as described later. Therefore, the light absorption region 33 can also be identified using a defect density as follows. That is, the defect density of the light absorption region 33 is higher than the defect density of an inner region 37 positioned inward relative to the light absorption region 33 in the mesa portion 32. The inner region 37 of the mesa portion 32 is positioned between the light absorption region 33 and the insulating layer 20. The defect density can be analyzed by acquiring a cross-sectional image of the mesa portion 32 including the light absorption region 33 and the inner region 37 of the mesa portion 32 using a (scanning) transmission electron microscope ((S) TEM), and counting the number of defects per unit area.

In the light absorption region 33, the absorbed light generates electrons and holes. The electrons flow from the light absorption region 33 to the n-type region 31n to which a positive potential is applied. The holes flow from the light absorption region 33 to the p-type region 31p to which a ground potential or a negative potential is applied. Thus, a current is extracted to an external circuit connected to the n-type region 31n and the p-type region 31p.

Light can be incident from an end surface of the mesa portion 32 (a surface parallel to the XZ plane) facing the third direction Y. The mesa portion 32 including the light absorption region 33 is formed on the substrate 10 into a protruding shape with a height in the first direction Z which is larger than a thickness of the n-type region 31n in the first direction Z and a thickness of the p-type region 31p in the first direction Z. Consequently, in a case in which light is incident from the end surface of the mesa portion 32 facing in the third direction Y, an incident area of the light can be increased. As a result, it is possible to increase absorption efficiency of light in the light absorption region 33 and improve the light-receiving sensitivity of the light-receiving element 1.

A length of the mesa portion 32 in the third direction Y is larger than a thickness of the light absorption region 33 of the mesa portion 32 in the first direction Z. Accordingly, in a case in which light is incident from the end surface of the mesa portion 32 facing in the third direction Y (a surface parallel to the XZ plane), the light can propagate in the third direction Y through a long distance and thus the light can be efficiently absorbed. The length of the mesa portion 32 in the third direction Y may be in a range from 10 times to 100 times greater than that in the first direction Z.

The length of the mesa portion 32 in the third direction Y is preferably larger than the length of the mesa portion 32 in the second direction X. Accordingly, in a case in which light is incident from the end surface of the mesa portion 32 facing in the third direction Y (a surface parallel to the XZ plane), the light can propagate in the third direction Y through a long distance and thus the light can be efficiently absorbed. The length of the mesa portion 32 in the third direction Y may be in a range from 1 time to 10 times greater than that in the second direction X.

Because the lateral surface(s) 32B of the mesa portion 32 are inclined such that the length of the mesa portion 32 in the second direction X decreases from the lower surface 32C toward the upper surface 32A, the light absorption region 33 can be formed not only in the surface layer region including the upper surface 32A of the mesa portion 32, but also in the surface layer region including the lateral surface(s) 32B of the mesa portion 32 by ion implantation described later. As a result, the area of the light absorption region 33 can be increased, and the light-receiving sensitivity of the light-receiving element 1 can be improved.

The light-receiving element 1 according to the embodiment can further include an n-side electrode 40n arranged on the n-type region 31n and a p-side electrode 40p arranged on the p-type region 31p. The n-side electrode 40n is in contact with the n-type region 31n and is electrically connected to the n-type region 31n. The p-side electrode 40p is in contact with the p-type region 31p and is electrically connected to the p-type region 31p. The n-type region 31n can be electrically connected to an external circuit through the n-side electrode 40n, and the p-type region 31p can be electrically connected to the external circuit through the p-side electrode 40p.

The light-receiving element 1 according to the embodiment may further include the insulating film 50 covering at least the upper surface 32A and the lateral surface(s) 32B of the mesa portion 32. The insulating film 50 protects the upper surface 32A and the lateral surface(s) 32B of the mesa portion 32. Accordingly, a current applied by the n-side electrode 40n and the p-side electrode 40p is less likely to leak through an upper surface of the p-type region 31p, the lateral surface(s) 32B of the mesa portion 32, the upper surface 32A of the mesa portion 32, and an upper surface of the n-type region 31n. Because the leakage current is reduced, a dark current is reduced when no light is incident on the light absorption region 33. As the insulating film 50, a silicon oxide film can be used, for example.

In the present embodiment, the insulating film 50 covers the upper surface 32A and the lateral surface(s) 32B of the mesa portion 32, the upper surface of the n-type region 31n, the upper surface of the p-type region 31p, the n-side electrode 40n, and the p-side electrode 40p. The insulating film 50 has an n-side opening 50n through which a part of an upper surface of the n-side electrode 40n is exposed, and a p-side opening 50p through which a part of an upper surface of the p-side electrode 40p is exposed. A wire that electrically connects the external circuit and the n-side electrode 40n can be bonded to the n-side electrode 40n in the n-side opening 50n. A wire that electrically connects the external circuit and the p-side electrode 40p can be bonded to the p-side electrode 40p in the p-side opening 50p.

The insulating film 50 may be a dielectric multilayer film. The insulating film 50 may be, for example, a dielectric multilayer film having a reflectance in a range from 90% to less than 100% relative to the wavelength of light incident on the light-receiving element 1. When light is incident from the end surface (a surface parallel to the XZ plane) of the mesa portion 32 facing in the third direction Y, the light is reflected by the insulating film 50 which is the dielectric multilayer film, so that it is possible to reduce loss caused by the light being extracted to the outside of the light-receiving element 1.

The thicknesses of the n-type region 31n and the p-type region 31p in the first direction Z is set smaller than the height of the mesa portion 32 in the first direction Z, so that each of the lower surfaces of the n-type region 31n and the p-type region 31p formed by ion implantation and annealing to be described later can be easily brought into contact with the insulating layer 20. Because the lower surface of the n-type region 31n and the lower surface of the p-type region 31p are in contact with the insulating layer 20, it is possible to reduce a leakage current flowing around below the lower surface of the n-type region 31n and below the lower surface of the p-type region 31p and then flowing to the n-type region 31n and the p-type region 31p, and it is thus possible to reduce the dark current when no light is incident on the light absorption region 33.

Preferably, the light absorption region 33 and the n-type region 31n are separated from each other in the second direction X in the semiconductor layer 30, and the light absorption region 33 and the p-type region 31p are separated from each other in the second direction X in the semiconductor layer 30. Thus, the dark current flowing between the light absorption region 33 and the n-type region 31n and the dark current flowing between the light absorption region 33 and the p-type region 31p can be reduced as compared with the case in which the light absorption region 33 is in contact with the n-type region 3 In and the p-type region 31p. The light absorption region 33 and the n-type region 31n can be separated from each other, for example, in a range from 1 μm to 10 μm in the second direction X, and the light absorption region 33 and the p-type region 31p can be separated from each other, for example, in a range from 1 μm to 10 μm in the second direction X.

A boundary region 34 is positioned between the light absorption region 33 and the n-type region 31n in the second direction X. A boundary region 35 is positioned between the light absorption region 33 and the p-type region 31p in the second direction X. An n-type impurity concentration in the boundary region 34 is lower than an n-type impurity concentration in the n-type region 31n. A p-type impurity concentration in the boundary region 35 is lower than a p-type impurity concentration in the p-type region 31p. Therefore, an electrical resistivity of the boundary region 34 between the light absorption region 33 and the n-type region 31n, and an electrical resistivity of the boundary region 35 between the light absorption region 33 and the p-type region 31p are higher than both an electrical resistivity of the n-type region 31n, and an electrical resistivity of the p-type region 31p. This allows for easier reduction in the dark current flowing between the light absorption region 33 and the n-type region 31n and the dark current flowing between the light absorption region 33 and the p-type region 31p. The electrical resistivity of the boundary region 34 and the electrical resistivity of the boundary region 35 can be measured by a spreading resistance analysis (SRA) method. The impurity concentration of the boundary region 34 and the impurity concentration of the boundary region 35 can be analyzed using NonoSIMS that can measure a minute region in secondary ion mass spectrometry (SIMS).

The height of the mesa portion 32 in the first direction Z is, for example, in a range from 2 μm to 100 μm. A length of the upper surface 32A of the mesa portion 32 in the second direction X is, for example, in a range from 10 μm to 100 μm. A thickness of the light absorption region 33 on a center line C is, for example, 1.5 μm or less. This center line is defined as the center of the upper surface 32A of the mesa portion 32 in the second direction X, and extends in the first direction Z. The thickness of the n-type region 31n in the first direction Z and the thickness of the p-type region 31p in the first direction Z are, for example, 1.5 μm or less. A thickness of the light absorption region 33 positioned at the lateral surface(s) 32B of the mesa portion 32 is, for example, 1.5 μm or less in a direction perpendicular to the lateral surface(s) 32B.

### Light-Receiving Device

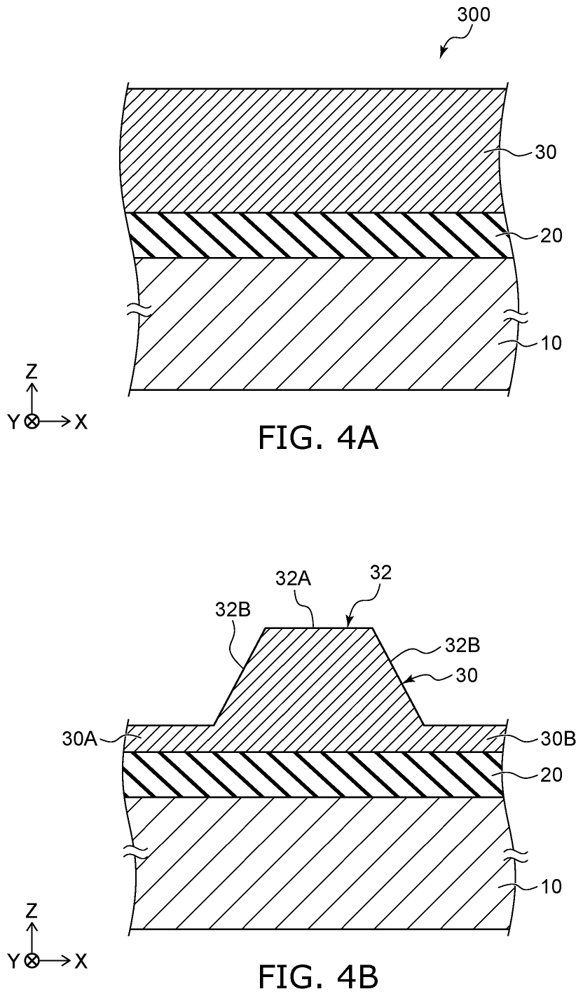

As illustrated in FIG. 3, a light-receiving device 100 according to the embodiment includes the above-described light-receiving element 1 and a lens 63. An end surface 36 of the mesa portion 32 of the light-receiving element 1 facing in the third direction Y is a light incident surface of the light-receiving element 1 and faces the lens 63 in the third direction Y. The lens 63 condenses light from the outside toward the end surface 36 of the mesa portion 32.

The light-receiving device 100 may further include a support member 61, a cap 62, a wiring substrate 66, a wire 67, a lead 64, and a lead 65.

The light-receiving element 1 is arranged on the wiring substrate 66 such that the substrate 10 faces the wiring substrate 66 in the first direction Z. Each of the n-side electrode 40n and the p-side electrode 40p of the light-receiving element 1 is electrically connected to a wiring portion of the wiring substrate 66 through, for example, the wire 67 formed of gold (Au). The wiring substrate 66 is supported on the support member 61. The cap 62 is arranged on the support member 61 and defines a space in which the wiring substrate 66, the light-receiving element 1, and the wire 67 are arranged. The lead 64 and the lead 65 extend from the support member 61 to the outside of the space defined by the cap 62. One of the leads 64 and 65 is electrically connected to the n-side electrode 40n through the wire 67, and the other is electrically connected to the p-side electrode 40p through the wire 67. The lens 63 is arranged in an opening 62A formed in the cap 62.

In the present embodiment, it is considered that the light absorption region 33 can absorb infrared light having a wavelength longer than the wavelength corresponding to the band gap energy of silicon by using the defect level generated in a silicon crystal by ion implantation described later. Ions are not implanted into the inner region 37 inward of the light absorption region 33 of the mesa portion 32, and light (light in a visible band) having a wavelength shorter than the wavelength corresponding to the band gap energy inherent in silicon can be absorbed in the inner region 37. In a case in which the light-receiving element 1 does not need to detect visible light, the light-receiving device 100 may further include a visible light cut filter 68 arranged between the lens 63 and the end surface 36 (light incident surface) of the light-receiving element 1. Light from which visible light has been cut by the visible light cut filter 68 is incident on the end surface 36 of the light-receiving element 1.

As illustrated in FIG. 3, the light-receiving element 1 of the light-receiving device 100 receives light at the end surface 36 of the mesa portion 32. The lens 63 does not need to condense light only on the light absorption region 33, and may condense the light so that the light is incident on the light absorption region 33 and the inner region 37 of the mesa portion 32. This is because the light incident on the light absorption region 33 is absorbed in the process of propagating in the third direction Y (a −Y direction in FIG. 3), and thus the absorption amount increases even in a case in which the area of an irradiation surface of the light absorption region 33 is small. In addition, because the mesa portion 32 has the lateral surface(s) 32B inclined with respect to the upper surface 32A, the area of the light absorption region 33 is increased compared to the case in which the lateral surface(s) 32 are not inclined, and thus the amount of light absorption can be increased.

### Method of Manufacturing Light-Receiving Element

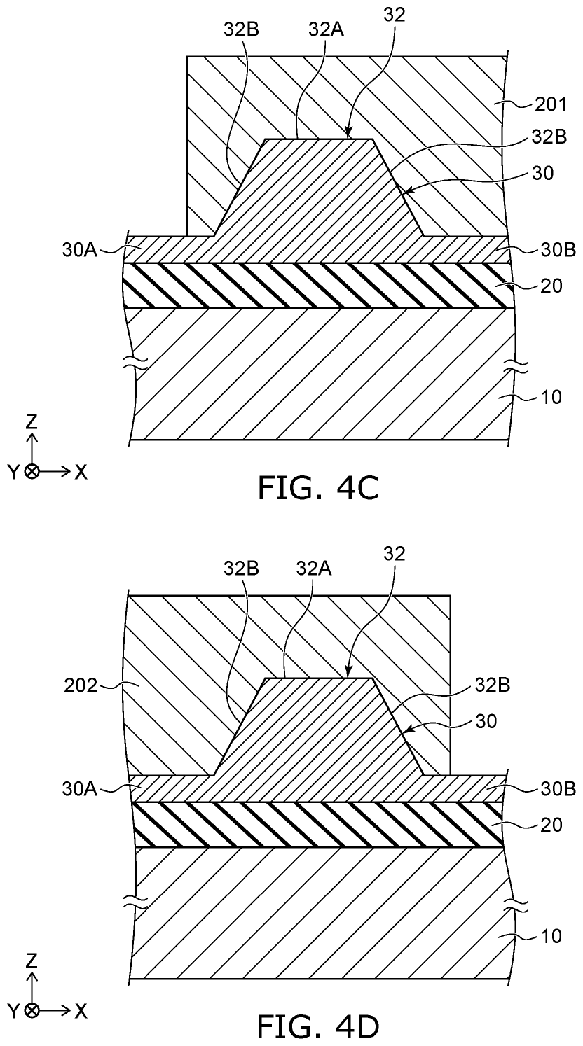

A method of manufacturing the light-receiving element 1 according to the embodiment will be described with reference to FIGS. 4A to 4F.

The method of manufacturing the light-receiving element 1 according to the embodiment includes a process of providing a structure 200 illustrated in FIG. 4E. The structure 200 includes the substrate 10, the semiconductor layer 30, and the insulating layer 20 positioned between the substrate 10 and the semiconductor layer 30 in the first direction Z. In the structure 200, the semiconductor layer 30 includes the n-type region 31n, the p-type region 31p, and the mesa portion 32 positioned between the n-type region 31n and the p-type region 31p in the second direction X. The mesa portion 32 includes the upper surface 32A and the lateral surface(s) 32B inclined with respect to the upper surface 32A. The length of the mesa portion 32 in the second direction X decreases from a side closer to the insulating layer 20 toward the upper surface 32A.

For example, the structure 200 can be provided through the processes illustrated in FIGS. 4A to 4E.

As illustrated in FIG. 4A, an SOI wafer 300 is provided in which the insulating layer 20 is arranged on the substrate 10, and the semiconductor layer 30 is arranged on the insulating layer 20.

A portion of the semiconductor layer 30 in the SOI wafer 300 is removed to form the mesa portion 32 in the semiconductor layer 30 as illustrated in FIG. 4B. For example, the mesa portion 32 can be formed by removing a portion of the semiconductor layer 30 by a reactive ion etching (RIE) method. In addition, the mesa portion 32 can be formed by a wet etching method. At this time, an angle of the lateral surface(s) 32B of the mesa portion 32 depends on plane orientation. Preferable method of forming the mesa portion 32 is RIE because the angle of the lateral surface(s) 32B of the mesa portion 32 can be easily selected. A first portion 30A and a second portion 30B of the semiconductor layer 30 remain on the insulating layer 20 in regions adjacent to the mesa portion 32 in the second direction X. A thickness of the first portion 30A in the first direction Z and a thickness of the second portion 30B in the first direction Z are smaller than the height of the mesa portion 32 in the first direction Z.

After the mesa portion 32 is formed, a p-type impurity is implanted with a predetermined energy into a part of the first portion 30A exposed from a first mask 201 in a state in which the part of the first portion 30A, the mesa portion 32, and the second portion 30B are covered with the first mask 201 as illustrated in FIG. 4C. For example, as the p-type impurity, boron (B) is implanted into the part of the first portion 30A exposed from the first mask 201 with an energy in a range from 5 keV to 700 keV. In a case in which other ions are implanted as the p-type impurity, the energy may be appropriately adjusted corresponding to a desired range.

After the mesa portion 32 is formed, an n-type impurity is implanted with a predetermined energy into the second portion 30B exposed from a second mask 202 in a state in which a part of the second portion 30B, the mesa portion 32, and the first portion 30A are covered with the second mask 202 as illustrated in FIG. 4D. For example, as the n-type impurity, phosphorus (P) is implanted into the part of the second portion 30B exposed from the second mask 202 with an energy in a range from 5 keV to 700 keV. In a case in which other ions are implanted as the n-type impurity, the energy may be appropriately adjusted corresponding to a desired range.

After the process of implanting the p-type impurity into the first portion 30A, the process of implanting the n-type impurity into the second portion 30B may be performed, or after the process of implanting the n-type impurity into the second portion 30B, the process of implanting the p-type impurity into the first portion 30A may be performed.

After the process of implanting the p-type impurity and the n-type impurity into the semiconductor layer 30, the semiconductor layer 30 is annealed at a temperature of, for example, 800° C. or higher. As a result, the p-type impurity and the n-type impurity can be activated. That is, as illustrated in FIG. 4E, the p-type region 31p is formed in the region in which the p-type impurity has been implanted, the n-type region 31n is formed in the region in which the n-type impurity has been implanted, and consequently, the structure 200 is provided. The annealing temperature is a temperature of the stage on which the SOI wafer 300 is held, and can be measured by a thermocouple.

The thickness of the first portion 30A in the first direction Z into which the p-type impurity is implanted, and the thickness of the second portion 30B in the first direction Z into which the n-type impurity is implanted are set smaller than the height of the mesa portion 32 in the first direction Z, so that the lower surface of the n-type region 31n and the lower surface of the p-type region 31p can be in contact with the insulating layer 20. Thus, as described above, the dark current in the light-receiving element 1 can be reduced.

The method of manufacturing the light-receiving element 1 according to the embodiment includes, after the process of providing the structure 200, a process of performing ion implantation with a predetermined energy from above the upper surface to the surface layer region including the upper surface 32A and the lateral surface(s) 32B of the mesa portion 32 in a state in which the n-type region 31n and the p-type region 31p are covered with a third mask 203 as illustrated in FIG. 4F. Thus, the light absorption region 33 is formed in the surface layer region including the upper surface 32A and the lateral surface(s) 32B of the mesa portion 32. For example, ions of silicon (Si), boron (B), germanium (Ge), magnesium (Mg), or the like are implanted into the surface layer region of the mesa portion 32 with a predetermined energy. For example, an energy with which a desired projected range is obtained is selected in a range from 5 keV to 700 keV.

Defects such as interstitial atoms and vacancies occur in the semiconductor crystal into which the ions have been implanted. The light absorption region 33 can absorb light having a wavelength longer than the wavelength corresponding to the band gap energy of the material (for example, silicon in the present embodiment) constituting the semiconductor layer 30 by using the defect level caused by the defects. Because the lateral surface(s) 32B of the mesa portion 32 are inclined such that the length of the mesa portion 32 in the second direction X decreases from a side closer to the insulating layer 20 toward the upper surface 32A, the light absorption region 33 can be formed by implanting ions also into the surface layer region including the lateral surface(s) 32B of the mesa portion 32.

According to the present embodiment, after ion implantation into the surface layer region of the mesa portion 32, annealing is not performed at a temperature of 800° C. or higher at which defects are recovered. This can realize light absorption using the defect level in the light absorption region 33. Annealing may be performed at a temperature less than 800° C., for example, may be performed at a temperature in a range from 300° C. to 600° C., or in a range from 450° C. to 550° C. Thus, the absorption coefficient can be improved.

For example, resist masks can be used as the first mask 201, the second mask 202, and the third mask 203. The resist mask can be removed by, for example, oxygen plasma ashing or a commercially available resist stripping solution after each process illustrated in FIGS. 4C, 4D, and 4F.

After the light absorption region 33 is formed, the third mask 203 is removed, and the insulating film 50, the n-side electrode 40n, and the p-side electrode 40p illustrated in FIG. 2 can be formed. The processes up to this stage are performed on a wafer, and the wafer is cut to be separated into individual light-receiving elements 1.

In the ion implantation process using the third mask 203, as illustrated in FIG. 4F, the third mask 203 further covers at least a portion 34A adjacent to the n-type region 31n in the semiconductor layer 30 between the n-type region 31n and the mesa portion 32, and at least a portion 35A adjacent to the p-type region 31p in the semiconductor layer 30 between the p-type region 31p and the mesa portion 32. The third mask 203 prevents ions from being implanted into the portion 34A and the portion 35A, so that the light absorption region 33 and the n-type region 31n are separated from each other in the second direction X, and the light absorption region 33 and the p-type region 31p are separated from each other in the second direction X. Thus, as described above, the dark current in the light-receiving element 1 can be reduced.

Results of first to third experiments will be described below. These results have led to the conception of the light-receiving element 1 of the embodiment.

### First Experiment

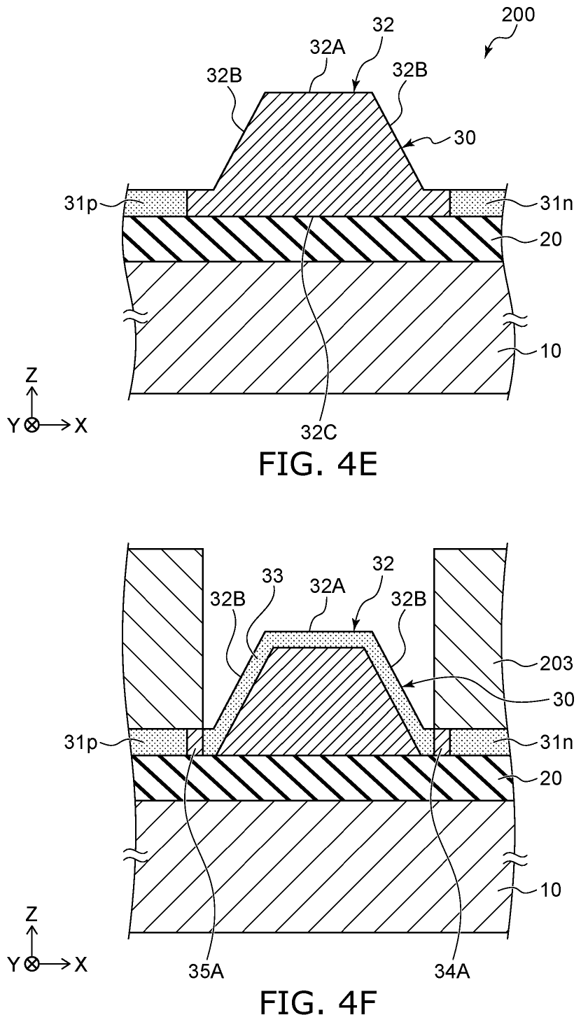

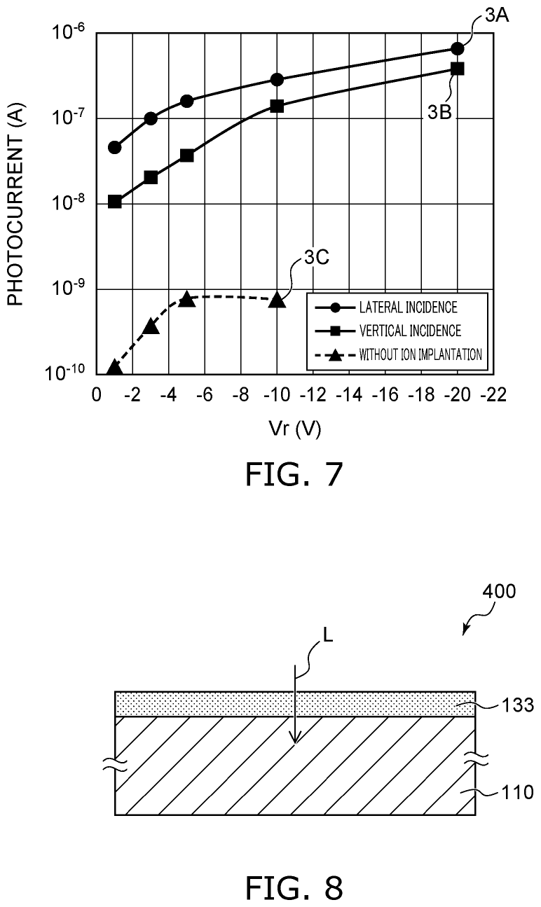

In a first experiment, a first sample 400 illustrated in FIG. 8 was provided. The first sample 400 included a light absorption layer 133 on a front surface of a silicon substrate 110. Five first samples 400 were provided in which the light absorption layer 133 was formed by implanting ions of helium (He), boron (B), silicon (Si), magnesium (Mg), germanium (Ge), or the like into the front surface of the silicon substrate 110. A relationship between the wavelength of light and an absorption coefficient was measured for each of the five first samples 400. Light L was vertically incident from an upper surface of the light absorption layer 133. The results are illustrated in FIG. 5. In FIG. 5, a horizontal axis represents the wavelength (nm) of incident light, and a vertical axis represents an absorption coefficient α (cm⁻¹) of the light absorption layer 133. In addition to the first sample, the silicon substrate 110 not including the light absorption layer 133 was provided, and the absorption coefficient α was also measured for this silicon substrate 110. The absorption coefficient α of the light absorption layer 133 was calculated by subtracting the amount of light absorbed in the silicon substrate 110, which was estimated from the absorption coefficient α of the silicon substrate 110, from the light transmittance of the first sample 400 measured with a spectrophotometer.

In FIG. 5, a broken line represents the result obtained when helium (He) was implanted. A chain line represents the result obtained when silicon (Si) was implanted. A solid line represents the result obtained when germanium (Ge) was implanted. A two-dot chain line represents the result obtained when boron (B) was implanted. A dotted line represents the result obtained when magnesium (Mg) was implanted. From the results of FIG. 5, it was confirmed that a light absorption layer for light in a near-infrared region of 2500 nm or less can be formed in the silicon crystal by the implantation of the above ion species.

### Second Experiment

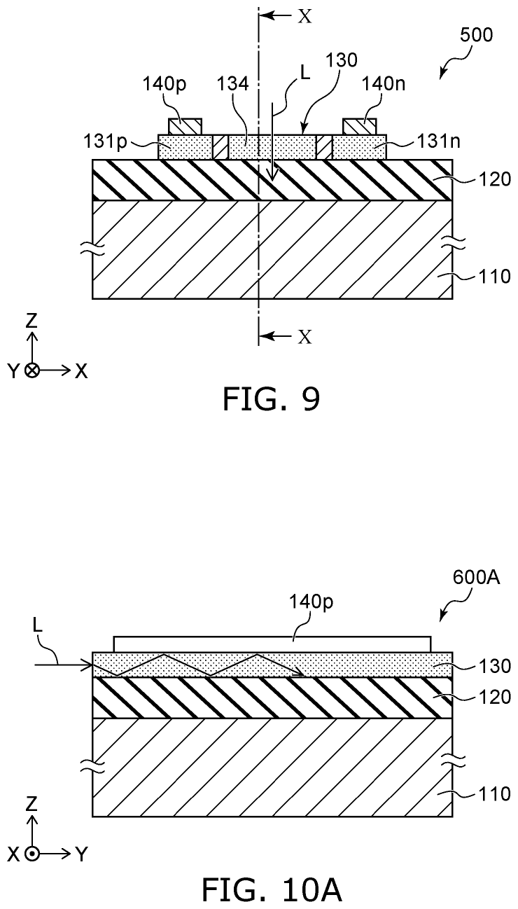

In a second experiment, a second sample 500 illustrated in FIG. 9 was provided. The second sample 500 included an SOI structure including a silicon substrate 110, a SiO₂ layer 120 formed on the silicon substrate 110, and a silicon layer 130 formed on the SiO₂ layer 120. The silicon layer 130 included an n-type region 131n, a p-type region 131p, and a light absorption region 134. The light absorption region 134 was positioned between the n-type region 13 In and the p-type region 131p in the second direction X. An n-side electrode 140n was arranged on the n-type region 131n. The n-type region 131n was electrically connected to the n-side electrode 140n. A p-side electrode 140p was arranged on the p-type region 131p. The p-type region 131p was electrically connected to the p-side electrode 140p. A thickness of the silicon layer 130 in the first direction Z was 0.5 μm. A length of the light absorption region 134 in the second direction X was 100 μm. A length of the light absorption region 134 in the third direction Y was 800 μm. The n-type region 13 In and the light absorption region 134 were separated from each other by 3 μm in the second direction X. The p-type region 131p and the light absorption region 134 were separated from each other by 3 μm in the second direction X.

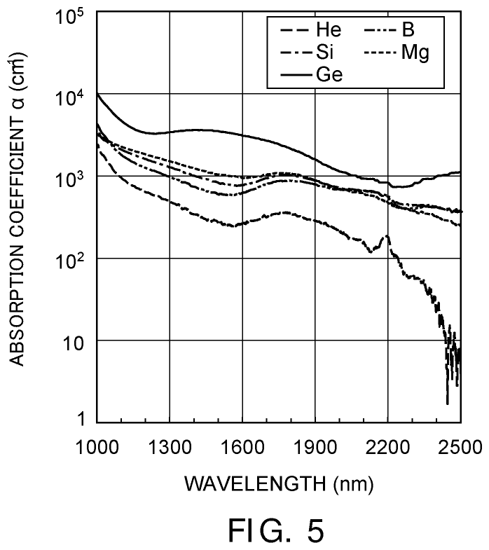

In the second experiment, responsivity was measured. The results are illustrated in FIG. 6. In FIG. 6, a horizontal axis represents the wavelength (nm) of incident light, and a vertical axis represents the responsivity (A/W). The responsivity represents a value obtained by dividing a photocurrent (A) by an amount of incident light (W).

In FIG. 6, a solid line represents the responsivity when boron (B) is implanted to form the light absorption region 134 in the second sample 500 illustrated in FIG. 9 and the light Lis vertically incident on the light absorption region 134. In FIG. 6, a two-dot chain line represents the responsivity when germanium (Ge) is implanted to form the light absorption region 134 in the second sample 500 illustrated in FIG. 9 and the light L is vertically incident on the light absorption region 134. In FIG. 6, a chain line represents the responsivity when the light Lis vertically incident on the light absorption region 134 which is not subjected to ion implantation and remains as a silicon layer in the second sample 500 illustrated in FIG. 9. In the second sample 500, the photocurrent was measured by a circuit connected to the n-side electrode 140n and the p-side electrode 140p. In FIG. 6, a broken line represents the responsivity of a commercially available silicon photodiode (manufactured by HAMAMATSU PHOTONICS K.K., model number S1337).

From the results illustrated in FIG. 6, when the light absorption region was formed by implanting B or Ge, the sensitivity to light in the near-infrared region could be increased by about three orders of magnitude as compared with the silicon photodiode. In addition, when the light absorption region was formed by implanting B or Ge, the sensitivity to light in the near-infrared region could be increased as compared with the light absorption region (silicon region) into which ions were not implanted.

### Third Experiment

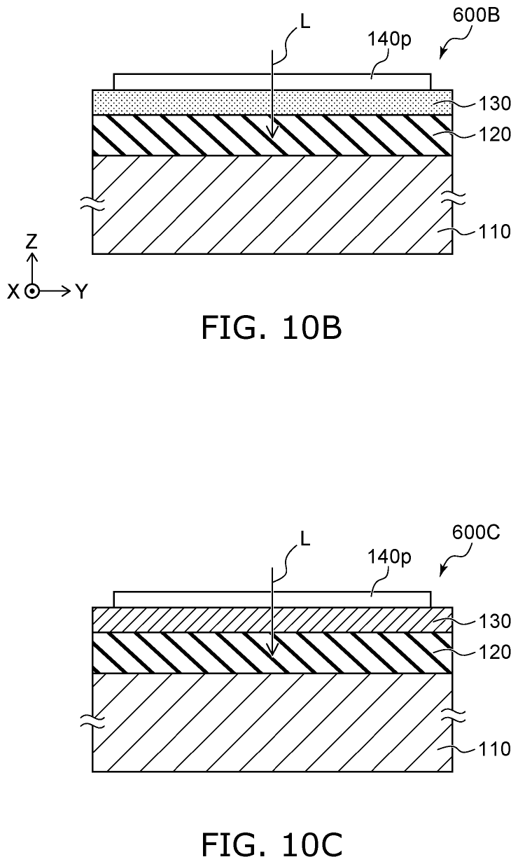

In a third experiment, a third-A sample 600A illustrated in FIG. 10A, a third-B sample 600B illustrated in FIG. 10B, and a third-C sample 600C illustrated in FIG. 10C were provided. Each of the third-A sample 600A, the third-B sample 600B, and the third-C sample 600C included an SOI structure including the silicon substrate 110, the SiO₂ layer 120 formed on the silicon substrate 110, and the silicon layer 130 formed on the SiO₂ layer 120. Boron (B) is implanted into the silicon layer 130 in each of the third-A sample 600A and the third-B sample 600B to form a light absorption region. Each of the third-A sample 600A and the third-B sample 600B had the same shape and dimensions as the second sample 500 illustrated in FIG. 9. FIGS. 10A and 10B are cross-sectional views taken along the line X-X in FIG. 9. Ions are not implanted into the silicon layer 130 of the third-C sample 600C.

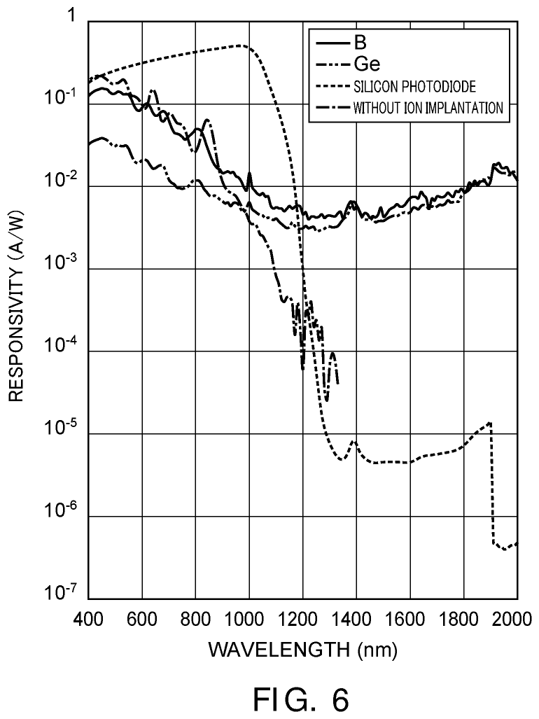

In the third experiment, photocurrent characteristics were measured when a laser beam having a wavelength of 1300 nm was incident. The power of the laser beam was set to 10 mW. As a result of observation with a microscope, the spot diameter (i.e., diameter) of the laser beam was about 100 μm at the position where the laser beam was incident on each sample. The results are illustrated in FIG. 7. In FIG. 7, the horizontal axis represents the applied voltage Vr (V), and the vertical axis represents the photocurrent (A).

In FIG. 7, 3A indicates a measurement result when the light L was incident from a lateral surface of the silicon layer 130 of the third-A sample 600A illustrated in FIG. 10A. In FIG. 7, 3B indicates a measurement result when the light L was incident vertically from an upper surface of the silicon layer 130 of the third-B sample 600B illustrated in FIG. 10B. In FIG. 7, 3C indicates a measurement result when the light L was incident vertically from the upper surface of the silicon layer 130 of the third-C sample 600C illustrated in FIG. 10C.

According to the results of FIG. 7, the photocurrent relative to the incident light of 1300 nm could be greatly increased by using the silicon layer 130 including the light absorption region formed by ion implantation as compared with the case of using the silicon layer 130 without ion implantation. Further, when the light L is incident from the lateral surface of the silicon layer 130, the photocurrent can be increased as compared with the case in which the light Lis vertically incident from the upper surface of the silicon layer 130. In particular, when the applied voltage is in a range from −1 V to −5 V, the photocurrent flowing in the third-A sample 600A was approximately four to five times higher than the photocurrent flowing in the third-B sample 600B.

When the third-A sample 600A in which the laser beam having a spot diameter of 100 μm is incident from the lateral surface having a thickness of 0.5 μm and a width of 100 μm is compared with the third-B sample 600B in which the laser beam having a spot diameter of 100 μm is incident from an upper surface having a width of 100 μm and a depth of 800 μm, it is found that the third-A sample 600A has a smaller proportion of the laser beam incident on the silicon layer 130. Despite this, a large amount of photocurrent flowed through the third-A sample 600A to which the laser beam was incident from the lateral surface. This is because laser beam L propagates through the silicon layer 130 as indicated by arrows in FIG. 10A. From the third experiment, it was found that even when the area of the incident surface is relatively small, the light absorption amount is improved by extending the light propagation distance.

The following was found from the first experiment to the third experiment. That is, it was found that the light absorption region that can absorb light having a wavelength longer than the wavelength corresponding to the band gap energy of the material constituting the semiconductor layer was formed by ion implantation. It was also found that the photocurrent can be amplified by making the light incident from the lateral surface and extending the propagation distance of the light.

Therefore, it is expected that the light-receiving element having the tapered mesa structure as described in the embodiment can increase the area of the light absorption region as compared with a light-receiving element having a non-tapered mesa structure, and can thus improve light-receiving efficiency of the light-receiving element.

Although the configuration of the light-receiving element has been described above by taking the case in which the semiconductor layer is formed of silicon as an example, the present invention is not limited thereto. The semiconductor layer may be a group III-V semiconductor. Also in this case, appropriately selecting the ion species for ion implantation makes it possible to form a light absorption region that can absorb light having a wavelength longer than the wavelength corresponding to the band gap energy of the material constituting the semiconductor layer.

Embodiments of the present disclosure have been described above with reference to specific examples. However, the present invention is not limited to these specific examples. All aspects that can be practiced by a person skilled in the art modifying the design as appropriate based on the above-described embodiment of the present invention are also included in the scope of the present invention, as long as they encompass the spirit of the present invention. In addition, in the scope of the concepts of the present invention, a person skilled in the art could conceive of various modifications and alterations, and those modifications and alterations will also fall within the scope of the present invention.

What is claimed is:

1. A light-receiving element comprising:
a substrate;
a semiconductor layer; and
an insulating layer positioned between the substrate and the semiconductor layer in a first direction, the first direction being a direction from the substrate toward the semiconductor layer, wherein:
the semiconductor layer comprises:
an n-type region,
a p-type region, and
a mesa portion positioned between the n-type region and the p-type region in a second direction orthogonal to the first direction, the mesa portion having an upper surface, and a lateral surface inclined with respect to the upper surface,
a length of the mesa portion in the second direction decreases from a side closer to the insulating layer toward the upper surface, and
the mesa portion comprises, in a surface layer region having the upper surface and the lateral surface, a light absorption region configured to absorb light having a wavelength longer than a wavelength corresponding to a band gap energy of a material constituting the semiconductor layer.

2. The light-receiving element according to claim 1, wherein the semiconductor layer is a silicon layer.

3. The light-receiving element according to claim 2, wherein the light absorption region contains boron, germanium, or magnesium in addition to silicon.

4. The light-receiving element according to claim 1, further comprising:
an insulating film covering the upper surface and the lateral surface of the mesa portion.

5. The light-receiving element according to claim 1, wherein a lower surface of the n-type region and a lower surface of the p-type region are in contact with the insulating layer.

6. The light-receiving element according to claim 1, wherein a height of the mesa portion in the first direction is in a range from 2 μm to 100 μm.

7. The light-receiving element according to claim 1, wherein a length of the upper surface of the mesa portion in the second direction is in a range from 10 μm to 100 μm.

8. The light-receiving element according to claim 1, wherein a thickness of the light absorption region on a center line is 1.5 μm or less, the center line being located at a center of the upper surface of the mesa portion in the second direction and extending in the first direction.

9. The light-receiving element according to claim 1, wherein a thickness of the n-type region in the first direction and a thickness of the p-type region in the first direction are each 1.5 μm or less.

10. The light-receiving element according to claim 1, wherein a defect density of the light absorption region is higher than a defect density of an inner region positioned inward relative to the light absorption region in the mesa portion.

11. The light-receiving element according to claim 1, wherein:
the light absorption region and the n-type region are separated from each other in the second direction in the semiconductor layer, and
the light absorption region and the p-type region are separated from each other in the second direction in the semiconductor layer.

12. The light-receiving element according to claim 11, wherein an electrical resistivity between the light absorption region and the n-type region, and an electrical resistivity between the light absorption region and the p-type region are higher than both an electrical resistivity of the n-type region and an electrical resistivity of the p-type region.

13. A light-receiving device comprising:
the light-receiving element according to claim 1; and
a lens configured to condense external light toward an end surface of the mesa portion, the end surface facing a third direction orthogonal to the first direction and the second direction.

14. A method of manufacturing a light-receiving element, the method comprising:
providing a structure comprising:
a substrate,
a semiconductor layer comprising:
an n-type region,
a p-type region, and
a mesa portion positioned between the n-type region and the p-type region in a second direction orthogonal to the first direction, wherein:
the mesa portion has an upper surface, and lateral surface inclined with respect to the upper surface, and
a length of the mesa portion in the second direction decreases from a side closer to the insulating layer toward the upper surface, and
an insulating layer positioned between the substrate and the semiconductor layer in a first direction, the first direction being a direction from the substrate toward the semiconductor layer; and
performing ion implantation with a predetermined energy from above the upper surface to a surface layer region including the upper surface and the lateral surface of the mesa portion in a state in which the n-type region and the p-type region are covered by a mask.

15. The method of manufacturing a light-receiving element according to claim 14, wherein the mask further covers at least a portion adjacent to the n-type region in the semiconductor layer between the n-type region and the mesa portion, and at least a portion adjacent to the p-type region in the semiconductor layer between the p-type region and the mesa portion.

16. The method of manufacturing a light-receiving element according to claim 14, wherein after the ion implantation, annealing is not performed at a temperature of 800° C. or higher.
